(19) United States
(12) Patent Application Publication
(10) Pub. No.: US 2002/0113603 A1
(43) Pub. Date: Aug. 22, 2002

(54) Method and apparatus using variable capacitance compensation for thickness shear mode sensors

(76) Inventor: James J. Spates, Albuquerque, NM (US)

Correspondence Address: Margaret Meta Brumm, Patent & Licensing Department, Nalco Chemical Company, One Nalco Center, Naperville, IL, 60563-1198, US

(21) Appl. No.: 09/750,566

(22) Filed: Dec. 28, 2000

(51) Int. Cl. G01R 27/26

(52) U.S. Cl. 324/675

(57) ABSTRACT

The present invention comprises a sensor apparatus used to measure surface mechanical loading such as a liquid loading that compensates for static capacitance in the sensor. The sensor includes a resonator and a variable capacitance device. The resonator and its concomitant circuitry has a static capacitance and is adapted to increase its motional impedance when exposed to surface mechanical loading. The variable capacitance device is connected to the resonator and is adapted to compensate for the static capacitance, whereby the range and linearity of the sensor apparatus are improved.

### FIELD OF THE INVENTION

This invention is in the general field of resonators. Specifically, this invention is in the field of sensors for compensating the static capacitance in resonators using variable capacitance compensation methods and circuits.

### BACKGROUND OF THE INVENTION

Acoustic devices are employed as effective mediums in the measurement of mass deposition, fluid properties, and viscoelastic properties. In vapor deposition systems resonators are used for monitoring coating thickness. In liquid the device may be used for sensing various surface loading conditions including properties of liquid in contact with the transducer such as the liquid density-viscosity product. Polymer film properties can be measured or if the surface of an acoustic device is treated with a chemically sensitive film various species of gas and vapors may be detected.

One type of acoustic sensor includes thickness shear mode resonators. Thickness shear mode resonators are referred to herein as “TSMR(s).” Currently available TSMRs generally consist of a thin quartz disk with metal electrodes (i.e., dielectric quartz). The metal electrodes are preferably formed as thin film electrodes on the spaced-apart surfaces of the quartz disk as is well known in the art. Applying a voltage across the electrodes generates an electric field that causes a shear deformation of the crystal. The quartz can be made to resonate at a frequency determined by the crystal thickness, among other factors.

Applying an areal mass deposition or liquid load to a TSMR increases the TSMR's motional impedance, affecting or decreasing the TSMR's resonant frequency. It should be appreciated that the electrical impedance of the TSMR near resonance completely characterizes the TSMR's response to a load as provided in Kanazawa and Gordon, “Frequency of a Quartz Microbalance in Contact with a Liquid,” Anal. Chem., 57, pp. 1770-1771, 1985. Network analyzer measurements of the impedance of the TSMR exposed to a liquid load demonstrate that the TSMR's impedance increases and correspondingly its resonant frequency decreases proportionally with (ρη)^{½} where ρ represents the liquid's certain density in (gm/cm³) and η represents the liquid's viscosity in (gm/s-cm).

To obtain good agreement with the impedance model or theoretical response described previously in Kanazawa and Gordon, and accurately determine a liquid's certain density ρ and viscosity η, the TSMR should be smooth and the resonator response measured using some test instrument other than an oscillator, preferably a network analyzer. However, for reasons of cost and portability, oscillators are used in the sensors to measure resonator response to surface mechanical loading.

A good oscillator implementation will: (1) follow the resonant frequency, providing an output of this parameter; and (2) maintain oscillation at high levels of surface loading, providing an output related to this loading. Many oscillators, however, have highly nonlinear responses and cannot track the TSMR's resonance frequency at high levels of liquid loading (ρη)^{½}. One of the major sources of oscillator/resonator system nonlinearity and reduced liquid loading range is the system's static capacitance (C_{static}), discussed in greater detail below. Moreover, it should be appreciated that it is sometimes desirable to place the resonator in harsh environments, where harsh environments are defined as environments with high temperatures or pressures. While resonators are designed for use in such harsh environments, oscillators are not, requiring that the oscillator be separate from, but connected to, the resonator by one or more wired connections, adding to the system's static capacitance (C_{static}).

One currently known solution to reducing or eliminating oscillator/resonator nonlinear response and improving, for instance, the liquid loading range of the TSMR is to use a Lever oscillator as described in Wessendorf, “The Lever Oscillator for Use in High Resistance Resonator Applications,” IEEE International Frequency Control Symposium, pp. 711-717, 1993; and Martin and Spates et al., “Resonator/Oscillator Response to Liquid Loading,” Anal. Chem., Vol. 69, No. 11, pp. 2050-2054, 1997. The Lever oscillator uses fixed inductors to compensate for the static capacitance.

Using the TSMR with a Lever oscillator requires that the technician calculates the static capacitance of the sensor and adds inductance (using standard “off the shelf” inductors) in parallel to the TSMR. The parallel resonance of the static capacitance and the inductor are hopefully equal to the sensor resonant frequency. Thus, the Lever oscillator is useful as long as the TSMR is used in applications for which the static capacitance can be readily calculated and adequate inductance introduced.

However, it should be appreciated that the static capacitance for all applications is not fixed, rather it changes from application to application due to the different sensor fixturing employed, among other factors. Therefore, unless a technician carries a wide variety of fixed inductors or has the luxury of having the time and resources to create custom inductors, the fixed inductance of the Level oscillator does not accurately compensate for all the static capacitance in a sensor.

It would be desirable to have alternative methods and devices to solve the compensation problem of static capacitance in sensors using TSMRs.

### SUMMARY OF THE INVENTION

The present invention comprises a sensor apparatus used to measure a surface mechanical load that compensates for static capacitance in the sensor. Compensating for the sensor's static capacitance improves the sensor's nonlinear response so that it approaches the theoretical response. Further, it enables the sensor to track the resonator's resonant frequency at higher levels of liquid loading (ρη)^{½}. The sensor includes a resonator and a variable capacitance device. The sensor has a static capacitance and the resonator is usually adapted to increase its motional impedance when exposed to mechanical loading. The variable capacitance device is connected to the resonator and is adapted to compensate for the static capacitance, whereby the range and linearity of the sensor apparatus are improved.

The present invention also comprises a variable capacitance compensation circuit. The variable capacitance circuit comprises a variable capacitor connected to an inductor. The variable capacitor and fixed inductor are arranged to compensate for static capacitance, preferably in an oscillating or resonating device.

A method of compensating for static capacitance in a sensor using a resonator is also contemplated. The method includes determining the static capacitance of the sensor; over compensating for the static capacitance using an inductor connected to the resonator; and compensating for any net inductance using at least one variable capacitor connected to the resonator.

### BRIEF DESCRIPTION OF THE FIGURES

FIG. 1 is a schematic of the equivalent circuit of a mass and liquid loaded thickness shear mode resonator (TSMR).

FIG. 2 is a schematic of one embodiment of a sensor using the TSMR of FIG. 1 with a variable capacitance compensation circuit.

FIG. 3 is a schematic of a second embodiment of a sensor using the TSMR of FIG. 1 with a variable capacitance compensation circuit.

FIG. 4 is a graph illustrating the change in oscillator frequency vs. liquid loading for various amounts of net capacitance Cₙ, the symbols are data points, the dotted line is the response predicted by Kanazawa and Gordon, and the solid lines are polynomial fits to the data.

FIG. 5 is a graph illustrating TSMR loss, measured as a change in damping voltage for various amounts of net capacitance Cₙ, the symbols are data points and the solid lines are polynomial fits to the data.

### DETAILED DESCRIPTION OF THE INVENTION

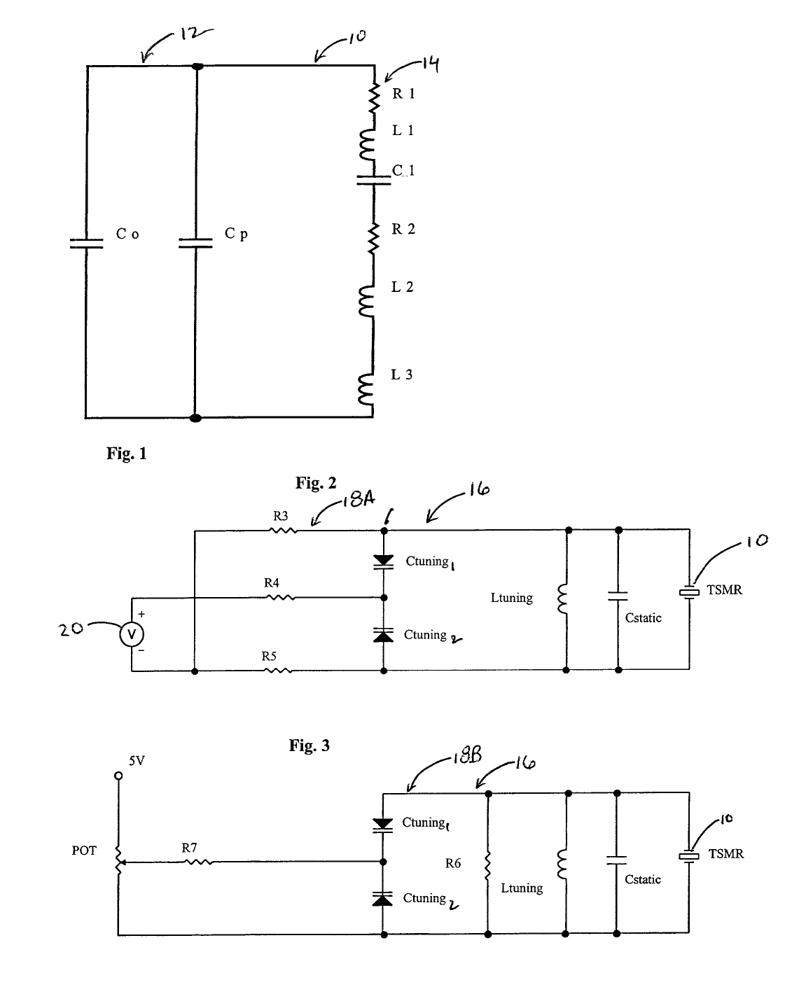

Referring now to the drawings, an equivalent-circuit model of the TSMR generally designated 10 and having a liquid load is illustrated in FIG. 1. As described by Martin and Granstaff et al. in “Characterization of a Quartz Microbalance with Simultaneous Mass and Liquid Loading,” Anal. Chem., Vol. 63, No. 20, pp. 2272-2281,1991, the equivalent-circuit model consists of a static capacitance (C_{static}) 12 in parallel with a “motional” branch 14 (i.e., R₁, L₁, C₁, R₂, L₂, L₃). The elements R₁, L₁ and C₁ represent the unperturbed, clean and dry resonator response; elements R₂ and L₂ represent the response of the liquid loading; element L₃ represents the inductance arising from the mass loading. There are other equivalent circuits depending upon the mechanical loading of the resonator. Bandey et al. in “Modeling the Responses of Thickness-Shear Mode Resonators Under Various Loading Conditions,” Anal. Chem., Vol.71, No. 11 pp. 2205-2214, 1999, describe twelve different surface perturbation types and each is characterized by a unique surface mechanical impedance. The surface loaded TSMR can also be described using a transmission line model. This model is also described by Bandey.

The static capacitance (C_{static}) 12 is shown electrically in parallel to the motional branch, where C_{static}=Cₒ+Cₚ, and C_{static} arises from capacitances internal and external to the TSMR. Internal capacitance (Cₒ) is that capacitance that arises from the TSMR, including the electrodes located on opposite sides of the dielectric quartz resonator. The parasitic external capacitance (Cₚ) is that capacitance that arises external to the TSMR, including but not limited to; the capacitance arising from the mechanical device the crystal is held in (i.e., the fixture), the oscillator, and any wires or electrical connections joining the oscillator and the TSMR.

The electrical response of the motional branch 14 arises from the electrically excited mechanical motion in the piezoelectric crystal of the TSMR 10. The static capacitance 12 of the TSMR 10 dominates the electrical behavior away from resonance, while the motional branch 14 dominates the electrical behavior near resonance. The unperturbed (dry) response of the TSMR is determined by the elements C_{static}, L₁, C₁ and R₁. The values for C_{static}, L₁, C₁ and R₁ can be determined by measuring the electrical response of the unperturbed TSMR over a range of frequencies near resonance and fitting the equivalent-circuit model to that data.

As provided in Martin and Spates, when the TSMR is operated in contact with a liquid, motional impedance increases due to liquid coupling to the surface, which is represented by the motional inductance (L₂) and resistance (R₂) in the equivalent-circuit model:

$${R}_{2} = {ω}_{2} {L}_{2} = \frac{n {ω}_{s} {L}_{1}}{N π} {( \frac{2 {ω}_{s} ρη}{{μ}_{q} {ρ}_{q}} )}^{1 / 2}$$

where:

n=the number of sides in contact with liquid;

N=the harmonic number;

ωₛ=the angular frequency at series resonance;

ρ_{q}=density of the quartz; and

μ_{q}=shear stiffness of the quartz;

ρ=liquid density (gm/cm³)

η=liquid viscosity (gm/s-cm).

The elements L₂ and R₂ of the motional branch represents kinetic energy storage and power dissipation, respectively, in the contacting fluid and each is proportional to (ρη)^{½}.

Martin and Spates define the series resonant frequency fₛ, for a liquid loaded TSMR, as the frequency at which the motional reactance vanishes (i.e., the motional impedance becomes real), providing:

$$fs = \frac{1}{2 π \sqrt{( {L}_{1} + {L}_{2} ) {C}_{1}}}$$

The change in fₛ (or Δfₛ) caused by the liquid loading is calculated:

$$Δ {f}_{s} ≅ - \frac{{L}_{2} {f}_{s}}{2 {L}_{1}} = - \frac{2 {nf}_{s}^{2}}{N \sqrt{{μ}_{q} {ρ}_{q}}} {( \frac{ρη}{4 π {f}_{s}} )}^{1 / 2}$$

Therefore, as predicted by Kanazawa and Gordon, the change in resonant frequency (Δfₛ) of a TSMR with a liquid load varies proportionally with (ρη)^{½} where ρ represents the liquid's certain density and η represents the liquid's viscosity. In other words, for the equivalent-circuit model of the TSMR 10 illustrated in FIG. 1 with a liquid load, the TSMR's impedance increases, and thus correspondingly its resonant frequency decreases, proportionally with (ρη)^{½}. It should be appreciated that this change in resonant frequency is not due to changes in the resistance R₂ of the liquid load, rather the change is only due to the change in the inductance L₂ of the liquid load.

The present invention can use a fixed inductor (L_{tuning}) and one or more electronically variable capacitances (C_{tuning}) in parallel with the TSMR. The inductor and variable capacitances compensate for or cancel the oscillator/resonator and fixture capacitance (i.e., the sensor's static capacitance, C_{static}), where C_{static} comprises the resonator capacitance (Cₒ) and the fixture and oscillator capacitances (Cₚ) as provided above. Compensating for the static capacitance using variable capacitors greatly increases the range and linearity of the oscillator/resonator response to liquid loading. Adding inductance alone to compensate for the static capacitance may result in an amount of capacitance that is not compensated for, defined as net capacitance Cₙ, where:

Cₙ=(C_{tuning}/2)+C_{static}−[1/(ωₛ²L_{tuning})]

Therefore, C_{tuning} required to cancel out any net capacitance Cₙ can be determined by:

C_{tuning}=2(Cₙ+[1/(ωₛ²L_{tuning})]−C_{static})

Where:

ωₛ=2πfₛand,

fₛ=the series resonant frequency of the TSMR.

Currently available devices compensate for the static capacitance in the sensors using oscillators with fixed inductors forming a parallel L-C tank circuit. The oscillator using the L-C tank circuit compensates for static capacitance. However, the oscillator uses fixed inductors that may over compensate or under compensate the static capacitance.

Pursuant to the present invention variable capacitors C_{tuning} can be used to compensate for the sensor's static capacitance (C_{static}). Properly compensating for the sensor's static capacitance improves the sensor's nonlinear response so that it approaches the theoretical response. Further, it enables the sensor to track the resonator's resonance frequency at higher levels of surface mechanical loading such as liquid loading (ρη)^{½} when compared to oscillators with a compensation scheme using only fixed inductors.

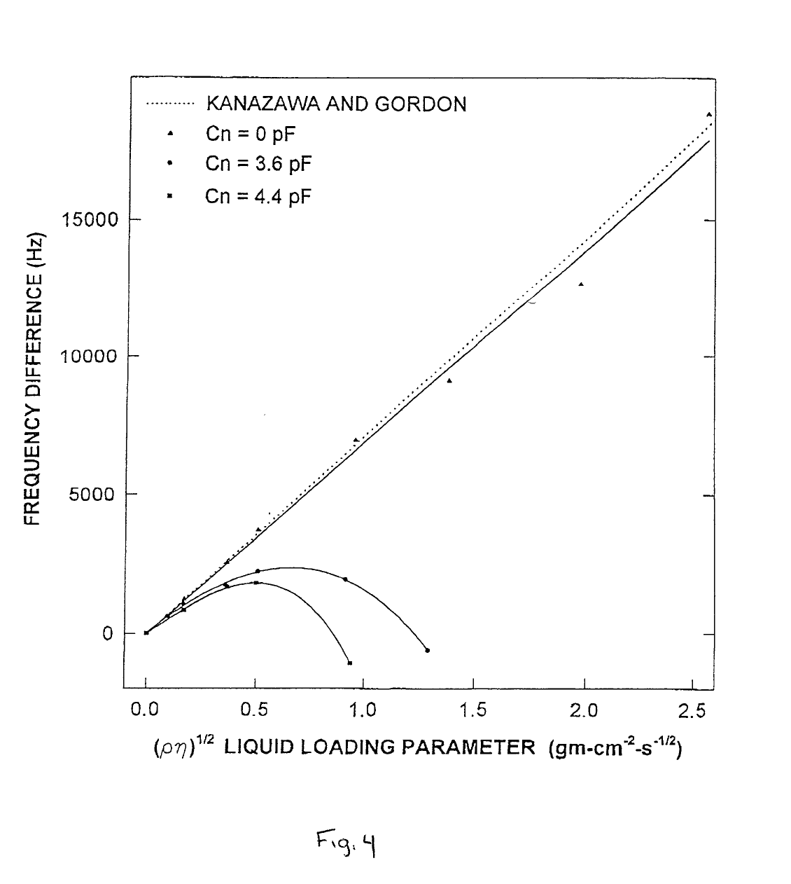

Two embodiments of a sensor including a variable capacitance circuit 16 connected in parallel to the TSMR are illustrated in FIGS. 2 and 3. Both embodiments include a variable capacitance device 18 connected to the TSMR and adapted to compensate for the static capacitance, whereby the range and linearity of the sensor are greatly improved. The variable capacitors are preferably PN junction diodes, wherein as the voltage across the junction increases, the capacitance decreases.

The first embodiment illustrated in FIG. 2 includes a variable capacitor compensation circuit 16 including a variable capacitance device 18A and a L_{tuning} inductor connected in parallel to the TSMR. The variable capacitance device 18A includes at least one variable capacitor C_{tuning} connected in parallel to the L_{tuning} inductor (in effect forming a variable capacitor tank circuit). Preferably, two variable capacitors C_{tuning} are connected together in series (by their cathodes) where the two capacitors are connected in parallel to the TSMR. It should be appreciated that the two variable capacitors C_{tuning} could be adjusted to the same value or different values depending upon the application.

The compensation circuit 16 of the embodiment illustrated in FIG. 2 also includes a voltage source 20 and at least one, but preferably three resistors R₃, R₄ and R₅. R₃ and R₅ are illustrated connected to the negative side of a power source 20 and the anode of the variable capacitors (C_{tuning}). R₄ is illustrated connected to the positive side of the power source 20 and the cathode of the variable capacitors (C_{tuning}). In the embodiment illustrated in FIG. 2, R₃, R₄ and R₅ each have a value of 100 k ohms respectively, although other resistance values are contemplated depending upon the application. Moreover, R₃, R₄ and R₅ could each have the same, or different values, again depending upon the application.

In the illustrated embodiment, the voltage source is used to control the variable capacitors (C_{tuning}), acting as the control device. However, other embodiments are contemplated wherein the control device comprises a digital to analog converter connected to a microprocessor to control the variable capacitors. The microprocessor is used to measure the sensor response to a known surface load such as a calibration fluid, and then determine the appropriate value for the C_{tuning}, which in combination with L_{tuning}, compensates for the C_{static}.

Another embodiment of the sensor with a variable capacitor circuit 16 is illustrated in FIG. 3. This embodiment includes a variable capacitor device 18B and a L_{tuning} inductor connected in parallel to the TSMR similar to that of FIG. 2. The variable capacitance device 18B includes two variable capacitors C_{tuning} (adjustable to the same or differing values) in parallel to the L_{tuning} inductor. However, this embodiment includes a resistor R₆ connected in parallel to the TSMR and the anodes of the variable capacitors (C_{tuning}). R₆ preferably has a value of 100 k ohms, although other values are contemplated. Additionally, the variable capacitor device 18B includes a resistor R₇ connected to a potentiometer (POT) and the cathode of the variable capacitors C_{tuning}, where the POT is used to manually adjust the variable capacitance and compensate for C_{static}. In the illustrated embodiment, R₇ has a value of 100 k ohms and POT is connected to a 5V source.

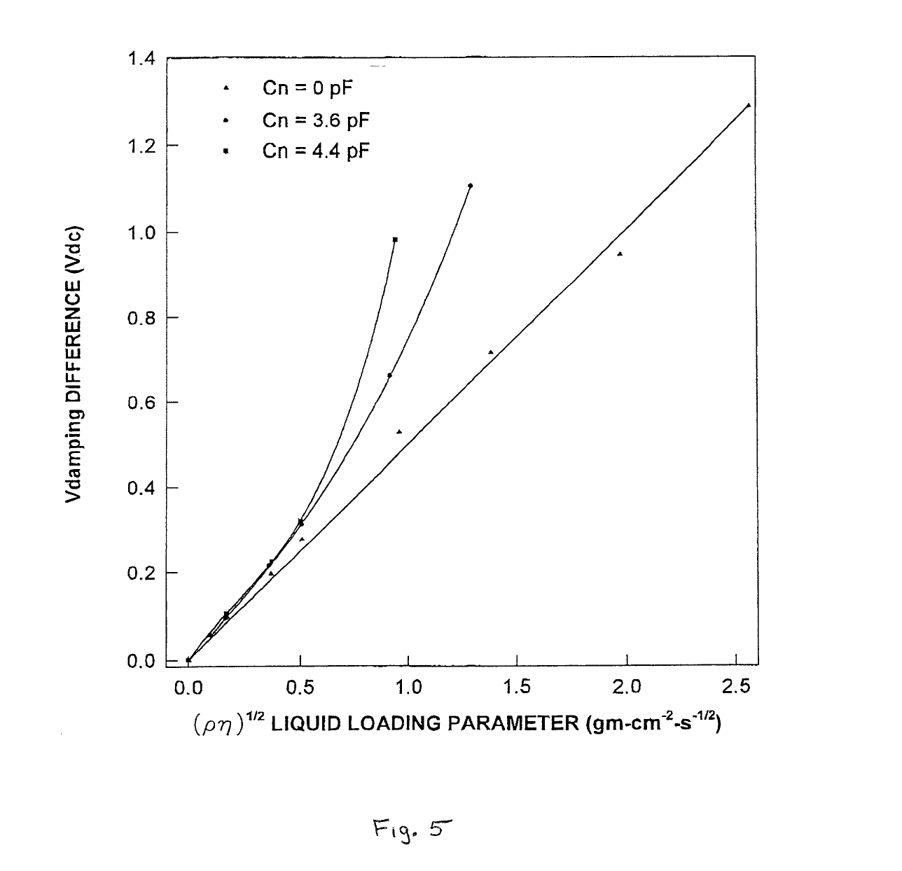

The effectiveness of a sensor employing the variable capacitance device of the present invention is demonstrated in FIGS. 4 and 5. A clean and dry sensor is loaded with liquids having various values of liquid loading parameters (ρη)^{½} (i.e., known density and viscosity) and the response of the sensor to the liquid loading is observed. FIG. 4 illustrates the frequency difference (Δfₛ) of a sensor including a 5MHz TSMR and compensation circuit of the present invention vs. liquid loading for various amounts of net capacitance Cₙ. The model response predicted by Kanazawa and Gordon is represented by a dotted line; the response to liquid loading for a sensor having a Cₙ=4.4 pF is represented by a line with solid squares; the response for a sensor having a Cₙ=3.6 pF is represented by a line with solid circles; and the response to liquid loading for a sensor having a Cₙ=0 pF is represented by a line with solid triangles. FIG. 4 demonstrates that, compensating for C_{static} using the present invention so that Cₙ=0 pF, improves the linearity of the oscillator/resonator response to liquid loading and the sensor closely approximates the theoretical response. In other words, as the net capacitance decreases, the oscillator/resonator response increases until it approaches the preferred theoretical response.

FIG. 5 illustrates the change in damping voltage (V_{damping}) of a sensor including a 5MHz TSMR and compensation circuit of the present invention vs. liquid loading for various amounts of net capacitance Cₙ. It should be appreciated that the change in damping voltage is a measure of TSMR loss. The response to liquid loading for a sensor having Cₙ=4.4 pF is represented by a line with solid squares; the response for a sensor having a Cₙ=3.6 pF is represented by a line with solid circles; and the response for a sensor liquid load having a Cₙ=0 pF is represented by a line with solid triangles. FIG. 5 demonstrates the improvement in linearity and range of the data curves where the variable capacitance device compensates for all of the C_{static} so that Cₙ=0 pF. In other words, TSMR loss decreases as net capacitance decreases.

An embodiment of the present invention illustrated in FIGS. 2 and 3 includes using L_{tuning} having an inductance ranging between approximately 22 μH to approximately 60 μH to compensate for C_{static}. This embodiment of the present invention includes using three inductors (22 μH, 27 μH or 33 μH) which are connected in parallel to the TSMR. The three inductors are arranged so that each inductor can be individually connected in parallel to the TSMR. Additionally, the three inductors can be connected to each other in parallel, in series or in some combination of the two (i.e., some of the inductors are connected to each other in parallel and some of the inductors are connected to each other in series) to create a composite or total L_{tuning} having an inductance ranging between approximately 22 μH to approximately 60 μH which is connected in parallel to the TSMR.

In an embodiment, the invention includes a circuit board comprising the three inductors, jumper connections and 12 connection positions. This enables the three inductors to be connected to the TSMR individually, or enables the inductors to be connected to each other in parallel, in series or in series/parallel and then connected to the TSMR in parallel.

In use, it may be advantageous to use the minimum capacitance value of the C_{tuning} to compensate for the C_{static}, so that the sensor includes L_{tuning} having a relatively large inductance value and a low C_{tuning} value. That is, one object of the invention is to add as little capacitance to the sensor as possible.

An inductor L_{tuning} having a large inductance value is inserted into the sensor to compensate for C_{static}, and Cₙ is determined. Preferably, Cₙ=0 pF. If not, the C_{tuning} is adjusted until C_{static} is compensated for and Cₙ=0 pF. If C_{tuning} cannot be adjusted until Cₙ=0 pF, the first inductor L_{tuning} is replaced with an inductor, or inductor combination having a lower inductance value and the above process is repeated until C_{static} is compensated for and Cₙ=0 pF.

The present invention can be used to measure surface mechanical loading, including, but not limited to; areal mass deposition and liquid loading in harsh environments. The present invention provides many advantages when compared to the currently available sensors. The variable capacitance device of the present invention compensates for the sensor's static capacitance improving the sensors' nonlinear response so that it approaches the theoretical response. Further, it enables the sensor to track the TSMR's resonant frequency at higher levels of surface mechanical loading than previously encountered with currently available sensors.

The present invention largely eliminates the variability of response from sensor to sensor due to differences in static capacitance. Using the present invention in conjunction with a TSMR provides a response close to the theoretical response. Since the compensated oscillator/resonator response can be made to agree closely with the theoretical response, viscosity standards traceable to the National Institute for Standards and Technology (NIST) can be used for calibration. The data is more useful since the data acquired allows meaningful comparisons from instrument to instrument without correction after the fact. It should be appreciated however that the variable capacitance compensation circuit is not limited to use only with sensors (with or without TSMRs). Rather, it is contemplated that the variable capacitance compensation circuit can be used with any oscillating or resonating device, or any other circuit or device, to compensate for static capacitance.

It should be understood that various changes and modifications to the presently preferred embodiments described herein will be apparent to those skilled in the art. Such changes and modifications can be made without departing from the spirit and scope of the present invention and without diminishing its present advantages. It is therefore intended that any such changes and modifications be covered by the appended claims.

The invention is hereby claimed as follows:

1. A sensor apparatus used for measuring a surface mechanical load comprising:
a resonator and its concomitant circuitry having a static capacitance; and
a variable capacitance device connected to the resonator and adapted to compensate for the static capacitance of the resonator and its concomitant circuitry.

2. The sensor apparatus of claim 1, wherein the variable capacitance device is connected in parallel to the resonator.

3. The sensor apparatus of claim 1, including an inductor connected to the variable capacitance device and the resonator.

4. The sensor apparatus of claim 1, wherein the variable capacitance device includes at least one variable capacitor.

5. The sensor apparatus of claim 1, wherein the variable capacitance device includes two variable capacitors connected in series.

6. The sensor apparatus of claim 1, wherein the variable capacitance device includes a voltage source connected to a cathode of a variable capacitor.

7. The sensor apparatus of claim 1, wherein the variable capacitance device includes a digital to analog converter controlled by a microprocessor device connected to and adapted to control at least one variable capacitor.

8. The sensor apparatus of claim 1, wherein the variable capacitance device includes a potentiometer connected to and adapted to control at least one variable capacitor.

9. The sensor apparatus of claim 8, wherein the variable capacitance device includes a voltage source connected to the potentiometer.

10. The sensor apparatus of claim 8, including a resistive element connected to at least the resonator.

11. A variable capacitance compensation circuit comprising:
a variable capacitor; and
an inductor element connected to the variable capacitor, and so constructed and arranged to compensate for static capacitance.

12. The variable capacitance compensation circuit of claim 11, including at least two variable capacitors connected together in series.

13. The variable capacitance compensation circuit of claim 1 1, including a voltage source connected to a cathode of the variable capacitor.

14. The variable capacitance compensation circuit of claim 11, including a resistive element connected to a cathode of the variable capacitor.

15. The variable capacitance compensation circuit of claim 11, including a resistive element connected to an anode of the variable capacitor.

16. The variable capacitance compensation circuit of claim 11 including a first resistive element connected to a cathode of the variable capacitor and a second resistive element connected to an anode of the variable capacitor.

17. The variable capacitance compensation circuit of claim 11, including a potentiometer connected to a cathode of the variable capacitor.

18. The variable capacitance compensation circuit of claim 17, wherein the control device includes a voltage source connected to the potentiometer.

19. A method of compensating for static capacitance in a sensor using a resonator, the method comprising:
determining the static capacitance of the resonator;
overcompensating for the static capacitance using a fixed inductor connected to the resonator; and
compensating for any net inductance using at least one variable capacitor connected to the resonator.

20. The method of compensating for static capacitance of claim 19, which includes compensating for the net capacitance by controlling the variable capacitor using a control device.
